(19) United States
(12) Patent Application Publication
(10) Pub. No.: US 2015/0108458 A1
(43) Pub. Date: Apr. 23, 2015

(54) ORGANIC EL ELEMENT, METHOD FOR MANUFACTURING THE SAME, ORGANIC EL DISPLAY PANEL, AND ORGANIC EL DISPLAY DEVICE

(71) Applicant: Panasonic Corporation, Osaka (JP)

(72) Inventors: MASAOMI SHIBATA, Osaka (JP); KENJI OKUMOTO, Osaka (JP); GOSUKE SAKAMOTO, Kyoto (JP)

(21) Appl. No.: 14/521,296

(22) Filed: Oct. 22, 2014

(30) Foreign Application Priority Data
Oct. 23, 2013 (JP) 2013-220357

(51) Int. Cl. H01L 51/50; H01L 27/32; H01L 51/56; H01L 51/52

(52) U.S. Cl. CPC H01L 51/5004; H01L 51/5012; H01L 51/5092; H01L 51/5206; H01L 27/3244; H01L 51/56; H01L 51/5056
USPC 257/40; 438/46

(57) ABSTRACT

An organic EL element of the present disclosure is an organic EL element having an inverted structure including a first hole injection layer containing a first organic material whose LUMO level is −4 eV or less. The organic EL element further includes a second hole injection layer containing a second organic material. The second hole injection layer is disposed between the first hole injection layer and an anode. The roughness of a principal surface of the second hole injection layer on the side of the anode is smaller than the roughness of a principal surface of the first hole injection layer on the side of the second hole injection layer. L1, L2, and EA satisfy formula: −EA−2 eV≦L2≦L1+2 eV, where the first organic material has a LUMO level L1, the second organic material has a LUMO level L2, and the anode has an electron affinity EA.

This application claims priority to Japanese Patent Application No. 2013-220357, filed on Oct. 23, 2013, the contents of which are hereby incorporated by reference.

### BACKGROUND

1. Field

The present disclosure relates to an organic electro luminescence (EL) element, a method for manufacturing the organic EL element, and an organic EL display panel and an organic EL display device including the organic EL element.

2. Description of the Related Art

In recent years, organic EL display devices that use organic EL elements as luminescence elements have become widespread. Organic EL display devices have good viewability and high impact resistance because they include self-luminous organic EL display panels having a completely individual structure.

Organic EL elements have a basic structure in which an organic compound is sandwiched between electrode pairs of an anode and a cathode. In current-actuated organic EL elements, an organic compound transitions from an excitation state to a base state through a plurality of processes, such as carrier (hole and electron) injection from electrodes, carrier transport, and carrier recombination (excitation of organic compound), caused by voltage application. Thus, current driving organic EL elements emit light.

At present, organic compounds having excellent characteristics for all the processes have not been found. In general, in organic EL elements, a portion in which each of the above processes mainly occurs is separated into layers and each layer is composed of a material suitable for the corresponding process. The organic EL elements have a laminated structure including the layers, which are referred to as functional layers.

Examples of the functional layers include injection layers having good carrier injection characteristics, transport layers having good carrier transport characteristics, an emitting layer having a good luminous efficiency, and a blocking layer for blocking electrons or holes. At present, materials used for these functional layers are being developed in order to improve the performance of organic EL elements.

Japanese Unexamined Patent Application Publication (Translation of PCT Application) No. 2007-533073 discloses that an organic material having a low LUMO level of −4 eV or less (hereafter referred to as “low LUMO material”) is used for a hole injection layer. According to this structure, holes which are generally generated between an anode and the hole injection layer, are generated between the hole injection layer and a hole transport layer (or an emitting layer).

Herein, the anode only conducts electrons extracted to the hole injection layer and thus an unstable interface between the anode and the hole injection layer can be removed from the carrier formation process. This stabilizes the driving voltage and increases the luminous life of the organic EL element. In fact, an increase in the luminous life of the organic EL element having the structure has been reported in Japanese Unexamined Patent Application Publication (Translation of PCT Application) No. 2003-519432.

In addition to the materials, the structures of the organic EL element have also been developed. Applied Physics Letters 89, 053503 (2006) discloses an inverted structure in which layers of an organic EL element are laminated in the opposite order, that is, a structure in which a substrate, a cathode, functional layers, and an anode are laminated in that order. Such an organic EL element having an inverted structure is useful because the device design flexibility is improved.

In particular, the quick responsiveness of a thin film transistor (TFT) element for driving an organic EL element is required in order to increase the size of an organic EL display panel. Thus, an n-type TFT element that uses electrons having higher mobility than holes as carriers is preferably used. If a pixel is constituted by the n-type TFT element and the organic EL element having an inverted structure, the organic EL element is connected to the drain of the TFT element. Therefore, the source potential of the TFT element is not affected by individual variation in organic EL elements. This reduces the variation in gate-source voltage of the TFT element among pixels and also reduces the luminance variation among pixels in the organic EL display panel.

### SUMMARY

The present disclosure provides an organic EL element that has an inverted structure and uses a low LUMO material for a hole injection layer. In the organic EL element, the luminescence unevenness and an increase in the driving voltage are suppressed.

An organic EL element according to an embodiment of the present disclosure includes a substrate, a cathode, an emitting layer, a first hole injection layer containing a first organic material whose LUMO level is −4 eV or less, and an anode disposed in that order. The organic EL element also includes a second hole injection layer containing a second organic material, the second hole injection layer being disposed between the first hole injection layer and the anode. The roughness of a principal surface of the second hole injection layer on the anode side is smaller than the roughness of a principal surface of the first hole injection layer on the anode side. The first organic material has a LUMO level L1. The second organic material has a LUMO level L2. The anode has an electron affinity EA. L1, L2, and EA satisfy formula (1) below.

−EA−2 eV≦L2≦L1+2 eV (1)

Since the organic EL element according to the above embodiment has an inverted structure and uses a low LUMO material for the first hole injection layer, the luminous life and the design flexibility are improved.

In the organic EL element according to the above embodiment, the anode is formed on a principal surface with a relatively low roughness because of the presence of the second hole injection layer, and an interface of the anode on the cathode side is brought into a good state. Consequently, luminescence unevenness is suppressed.

Furthermore, in the organic EL element according to the above embodiment, a portion that allows efficient carrier injection is sufficiently ensured and an increase in the driving voltage is suppressed.

Additional benefits and advantages of the disclosed embodiments will be apparent from the specification and Figures. The benefits and/or advantages may foe individually provided by the various embodiments and features of the specification and Figures, and need not all be provided in order to obtain one or more of the same.

### BRIEF DESCRIPTION OF THE DRAWINGS

FIG. 1A is a schematic sectional view showing an organic EL element according to a first embodiment;

FIG. 2A is a schematic view for describing the movement of carriers in an organic EL element;

FIG. 2B is a schematic view for describing the movement of carriers in an organic EL element;

FIG. 3 is a graph showing the relationship between applied voltage and current density in Examples and Comparative Examples of the organic EL element;

FIG. 4 is a graph showing the relationship between applied voltage and current density in Examples of the organic EL element;

FIG. 5 is a block diagram schematically showing a structure of an organic EL display device according to a second embodiment;

FIG. 6 is an enlarged plan view schematically showing a screen of an organic EL display panel;

FIG. 7 is a schematic sectional view showing an organic EL element;

FIG. 8 is a plan view showing the luminescent state of the organic EL element;

FIG. 9A is an AFM image of a HAT-CN layer having a thickness of 10 nm;

FIG. 9B is an AFM image of a HAT-CN layer having a thickness of 25 nm;

FIG. 10 is a schematic sectional view showing an organic EL element;

FIG. 11A is a plan view showing the luminescent state of the organic EL element when the HAT-CN content is 15%;

FIG. 11B is a plan view showing the luminescent state of the organic EL element when the HAT-CN content is 50%;

FIG. 11C is a plan view showing the luminescent state of the organic EL element when the HAT-CN content is 90%; and

FIG. 12 is a graph showing the relationship between the HAT-CN content in the hole injection layer and the driving voltage.

### DESCRIPTION OF THE EMBODIMENTS

First, the terms used in the present application will be described below.

The term “LUMO” stands for a lowest unoccupied molecular orbital and the term “HOMO” stands for a highest occupied molecular orbital. The term “LUMO level” indicates an energy level of the LUMO and the term “HOMO level” indicates an energy level of the HOMO. Note that the energy level is expressed as the chemical potential of electrons when the vacuum level is 0 eV. Therefore, electrons are stable at a low energy level and holes are stable at a high energy level.

The term “roughness of a principal surface” means the degree of rugged geometry on a principal surface and is specifically expressed as the maximum roughness or the average roughness. The term “maximum roughness” means a difference between the maximum distance (height) and the minimum distance (height) from a substrate principal surface to a target principal surface in a laminating direction. The term “laminating direction” means a direction orthogonal to the substrate principal surface. The term “average roughness” indicates a value obtained by summing the absolute values of differences between the measured heights of target interfaces and the average of the measured heights and by dividing the sum by the number of measurement points.

Hereafter, an organic EL element, a method for manufacturing the organic EL element, an organic EL display panel, and an organic EL display device according to embodiments of the present disclosure will be described with reference to the attached drawings. The drawings of this application include schematic views, and thus the scale of members may be different from that of actual members. Furthermore, the term “upper” in this application does not indicate an upper direction (vertical direction) in the absolute spatial perception, but is defined by the relative positional relationship based on the laminating order of a laminated structure of an organic EL element. Therefore, when a structure is laminated on a supporting member, the supporting member side is a lower side and the structure side is an upper side.

Studies that have Led to Embodiments of the Present Disclosure

The inventors of this application (hereafter referred to as “inventors”) have found that, when a low LUMO material is used for a hole injection layer in an organic EL element having an inverted structure, the luminance varies in a luminescent area of the organic EL element (hereafter referred to as “luminescence unevenness”). Such luminescence unevenness degrades the luminous quality of the organic EL element. The luminescence unevenness may cause a variation in the luminescence luminance among organic EL elements in a display panel.

In the course of overcoming the luminescence unevenness, the inventors have also found a problem in that the driving voltage of the organic EL element increases. The increase in the driving voltage produces various adverse effects such as a decrease in the luminous life of the organic EL element, degradation of electric power consumption, complicated drive circuits, and an increase in the cost of drive circuits.

Hereafter, the problems found by the inventors will be described in detail.

### 1. Finding of Luminescence Unevenness

The inventors have found that, when a low LUMO material is used for a hole injection layer in an organic EL element having an inverted structure, the luminescence unevenness occurs.

First, the inventors have manufactured an organic EL element 900a having an inverted structure in which HAT-CN, which is a low LUMO material, is used for a hole injection layer. Herein, HAT-CN represents 1,4,5,8,9,12-hexaazatriphenylene-2,3,6,7,10,11-hexacarbonitrile.

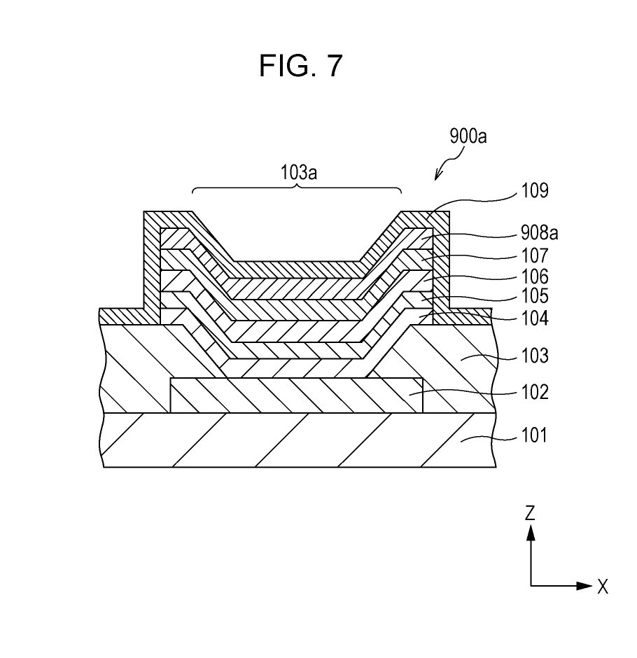

FIG. 7 is a schematic sectional view showing the organic EL element 900a. The organic EL element 900a is formed in an opening 103a of a bank 103 formed on a substrate 101. In the organic EL element 900a, a cathode 102, an electron injection layer 104, an electron transport layer 105, an emitting layer 106, a hole transport layer 107, a hole injection layer 908a, and an anode 109 are disposed in that order.

The bank 103 has a thickness of 1 μm. The exposed surface of the cathode 102 in the opening 103a has a square shape with a size of 2.3 mm×2.3 mm. The cathode 102 has a thickness of 100 nm. The electron injection layer 104 has a thickness of 3 nm. The electron transport layer 105 has a thickness of 20 nm. The emitting layer 106 has a thickness of 50 nm. The hole transport layer 107 has a thickness of 165 nm. The hole injection layer 908a has a thickness of 10 nm. The anode 109 has a thickness of 14 nm. The thickness of each functional layer is set so that light (red light) emitted from the emitting layer 106 is amplified by a cavity structure.

The electron injection layer 104, the electron transport layer 105, the emitting layer 106, the hole transport layer 107, the hole injection layer 908a, and the anode 109 formed in the opening 103a are all formed by vacuum vapor deposition at a vacuum of 4×10⁻⁴ Pa or less.

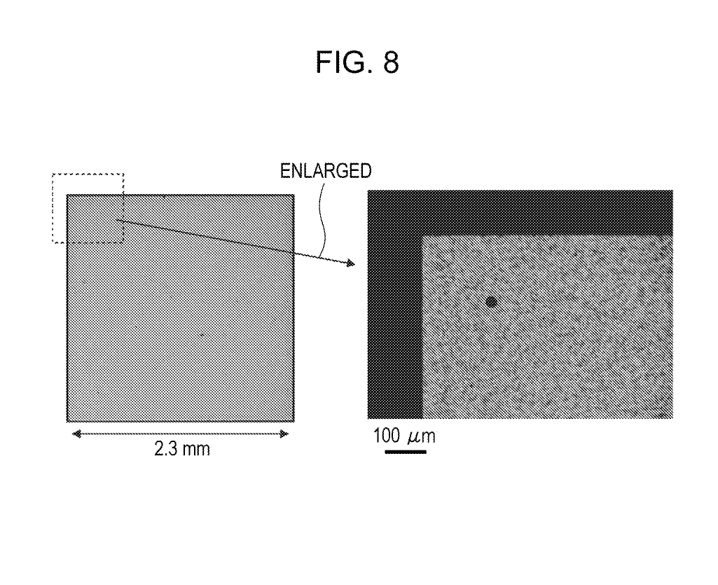

FIG. 8 is a plan view showing the luminescent state of the organic EL element 900a. The left drawing in FIG. 8 shows an exposed portion of the cathode 102 in the opening 103a, that is, the entire luminescent area. When a portion of the luminescent area of the organic EL element 900a is enlarged, as shown in the right drawing in FIG. 8, high-luminance portions and low-luminance portions are found to be scattered in the luminescent area. As described above, luminescence unevenness occurs in the organic EL element 900a having an inverted structure in which HAT-CN is used for the hole injection layer 903a.

### 2. Analysis of Luminescence Unevenness

The inventors have assumed that the luminescence unevenness is caused by a molecular structure of HAT-CN. To provide a very low LUMO level, namely −4 eV, as in the case of HAT-CN, the conjugated system needs to be sufficiently widespread in addition to the presence of an electron-withdrawing group in the molecule. In other words, a low LUMO material generally has a high flatness of a molecular structure.

In such a molecular structure, planes are easily stacked due to their shapes, and thus molecules are easily stacked in one direction. In particular, molecules are more easily stacked in a π conjugated system because planes are attracted by so-called π-π interactions (π-π stacking). A condensed aromatic ring formed by condensing monocyclic compounds in which single bonds and double bonds are alternately arranged has a flat skeleton. However, when the condensed aromatic ring bonds to a main chain or a side chain, the plane direction of the flat skeleton can freely change to some degree in the molecular structure due to the twist of the main chain or the side chain (that is, low flatness). As a result of the variation in the direction of the flat skeleton, the surface roughness of an interface is suppressed. On the other hand, when a flat skeleton such as a condensed aromatic ring is present in the central region of the molecular structure as in the case of HAT-ON, the flatness of the entire molecular structure increases even if a slightly bulky structure bonds to the side chain.

The inventors have considered that, in a layer composed of a low LUMO material, in particular, HAT-CN, many pillar-shaped structures in which molecules are stacked in one direction are formed and thus the rugged geometry is easily formed on a principal surface on the upper (anode) side (hereafter referred to as “upper surface”), which tends to increase the roughness. Herein, an anode is formed on a hole injection layer in an inverted structure. That is, in the organic EL element 900a, the anode 109 is formed on an upper surface of the hole injection layer 908a with a large roughness. Therefore, it is assumed that the interface is not satisfactorily formed and the luminescence unevenness occurs due to electrode separation or the like.

In the case where a material having a molecular structure with a high flatness is used, the rugged geometry of the surface increases compared with the case where a material having a molecular structure with a low flatness is used. Furthermore, use of a material, having a high flatness increases the proportion of the pillar-shaped structure in which flat skeletons are stacked in one direction.

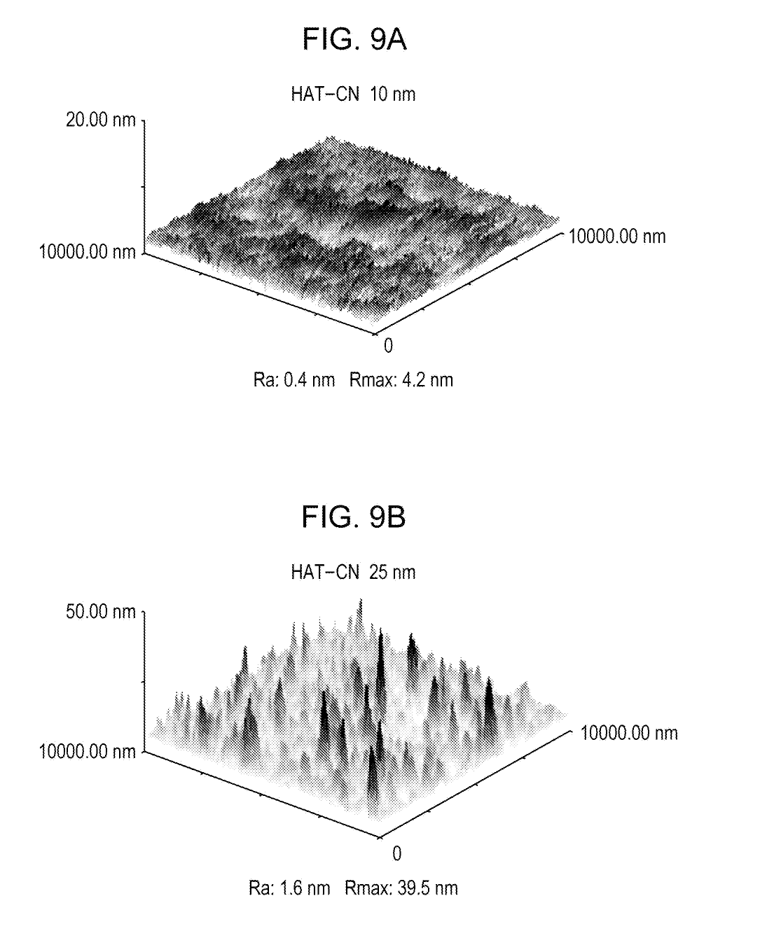

FIGS. 9A and 9B are atomic force microscope (AFM) images of a HAT-CH layer. FIG. 9A is an AFM image when the HAT-CN layer has a thickness of 10 nm and FIG. 9B is an AFM image when the HAT-CN layer has a thickness of 25 nm. In FIGS. 9A and 9B, Ra denotes the average roughness of an upper surface of the layer and Rmax denotes the maximum, roughness of an upper surface of the layer. FIGS. 9A and 9B are images of an element obtained by forming a HAT-CN layer on a glass substrate by vacuum vapor deposition, the images being observed with an AFM.

It is clear from the AFM images that the rugged geometry is formed on the upper surface of the HAT-CN layer, which supports the above assumption. It is found from the comparison between FIG. 9A and FIG. 9B that there is a positive correlation between the thickness of the HAT-CN layer and the roughness of the upper surface of the layer. For example, Rmax is 4.2 nm when the layer has a thickness of 10 nm and Rmax is 39.5 nm when the layer has a thickness of 25 nm. When the thickness of the layer is T nm, Rmax can be approximated to be 0.06×T² nm.

### 3. Suppression of Luminescence Unevenness

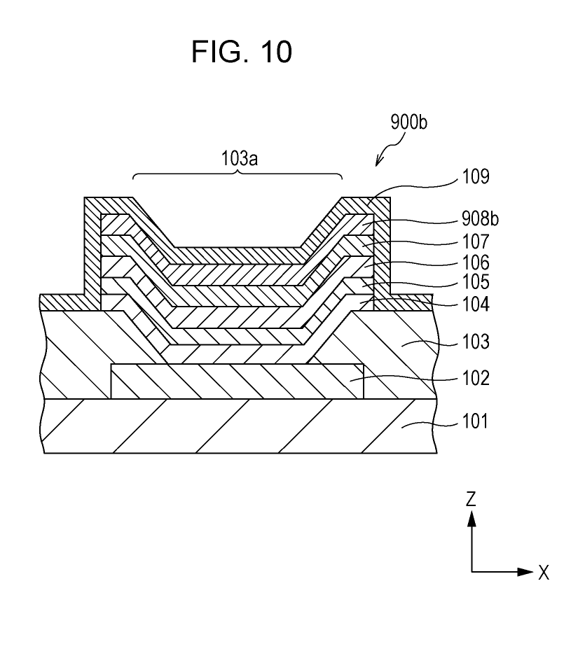

Subsequently, the inventors have manufactured an organic EL element 900b in which the roughness of an upper surface of the hole injection layer is decreased compared with the organic EL element 900a. FIG. 10 is a schematic sectional view showing the organic EL element 900b.

The organic SL element 900b is manufactured by changing the hole injection layer 908a of the organic EL element 900a to a hole injection layer 908b. The hole injection layer 908b is a mixed layer of NPB and HAT-CN and has a thickness of 10 nm. Note that NPB represents N,N′-diphenyl-N,N′-bis(1-naphthyl)benzidine.

NPB has a molecular structure with a relatively low flatness. Therefore, it is believed that the NPB inhibits the formation of the pillar-shaped structure of HAT-CN, whereby the roughness of the upper surface of the hole injection layer 908b is smaller than the roughness of the upper surface of the hole injection layer 908a.

In the organic EL element 900b, three elements whose HAT-CN contents are 15 vol %, 50 vol %, and 90 vol % have been manufactured in order to investigate the difference of the HAT-CN content in the hole injection layer 908b (hereafter, “%” means “vol %”).

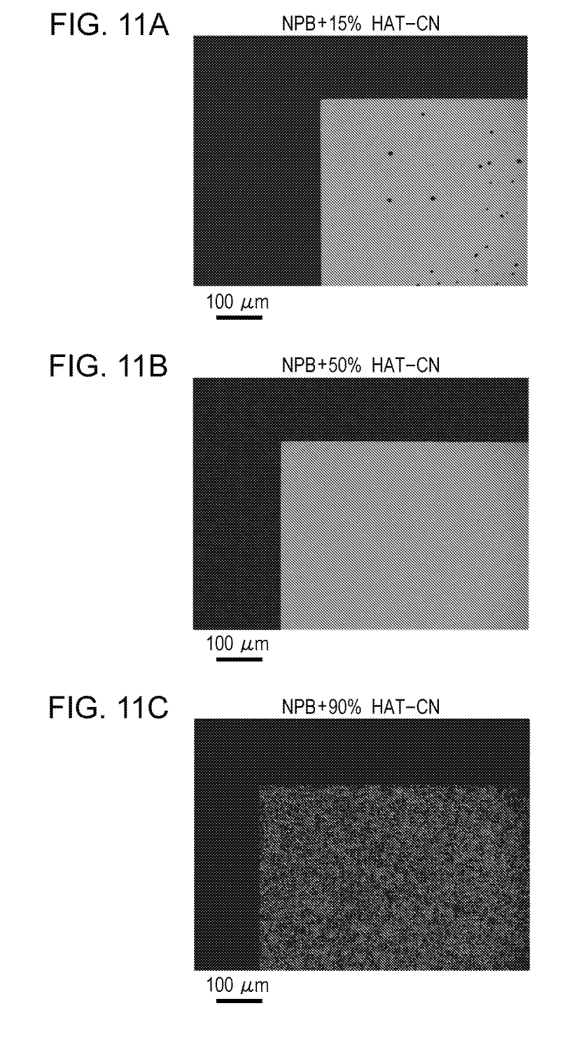

FIG. 11A is a plan view showing the luminescent, state of the organic EL element 900b when the HAT-CN content in the hole injection layer 908b is 15%. FIG. 11B is a plan view showing the luminescent state of the organic EL element 900b when the HAT-CN content in the hole injection layer 908b is 50%. FIG. 11C is a plan view showing the luminescent state of the organic EL element 900b when the HAT-CN content in the hole injection layer 908b is 90%.

As shown in FIGS. 11A and 11B, when the HAT-CN content in the hole injection layer 908b is in the range of 15% to 50%, the luminescence unevenness does not occur in the organic EL element 900b. This demonstrates that the roughness of the upper surface of the hole injection layer is decreased by mixing, into the hole injection layer, a material having a molecular structure with a relatively low flatness, such as NPB, which suppresses the luminescence unevenness.

In contrast, as shown in FIG. 11C, when the HAT-CN content in the hole injection layer 908b is 90%, the luminescence unevenness occurs. This may be because the NPB content in the hole injection layer 908b is decreased, which prevents the roughness of the upper surface of the hole injection layer 908b from being sufficiently decreased.

### 4. Finding of Other Problems

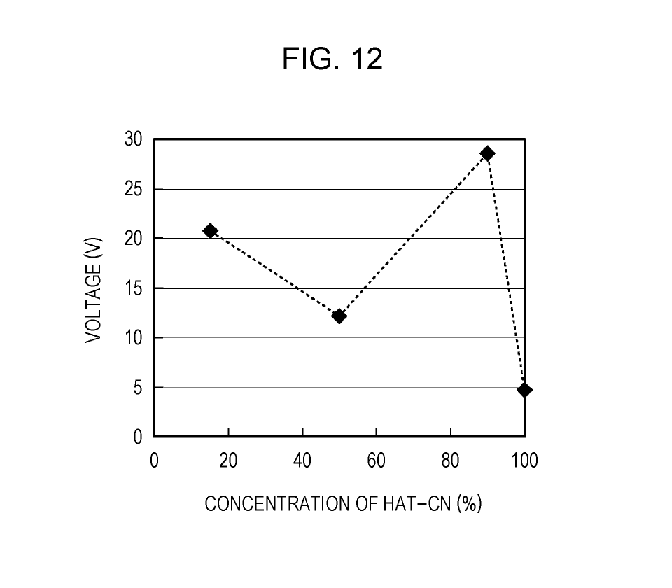

The inventors have found that other problems are posed in the organic EL element 900b. FIG. 12 is a graph showing the relationship between the HAT-CN content (horizontal axis) in the hole injection layer 908b and the driving voltage (vertical axis). Note that the driving voltage is a voltage that provides a current density of more than 10 mA/cm². In FIG. 12, the driving voltage at a HAT-CN content of 100% is illustrated. The driving voltage is a driving voltage of the organic EL element 900a.

The organic EL element 900a (the HAT-CN content is 100%) has a satisfactory driving voltage of about 5 V whereas the organic EL element 900b in which the hole injection layer 908b is a mixed layer of HAT-CN and NPB has a high driving voltage of more than 10 V. The increase in the driving voltage produces various adverse effects such as a decrease in the luminous life of the organic EL element, degradation of electric power consumption, complicated, drive circuits, and an increase in the cost of drive circuits. In particular, when the driving voltage exceeds 10 V as in the organic EL element 900b, such an organic EL element is not in practical use and thus some improvement is required. Accordingly, the inventors have found an embodiment of the present disclosure described below.

### SUMMARY OF EMBODIMENTS OF THE PRESENT DISCLOSURE

An organic EL element according to an embodiment of the present disclosure includes a substrate, a cathode, an emitting layer, a first hole injection layer containing a first organic material whose LUMO level is −4 eV or less, and an anode disposed in that order. The organic EL element also includes a second hole injection layer containing a second organic material, the second hole injection layer being disposed between the first hole injection layer and the anode. A roughness of a principal surface of the second hole injection layer on the side of the anode is smaller than a roughness of a principal surface of the first hole injection layer on the side of the second hole injection layer. The first organic material has a LUMO level L1. The second organic material has a LUMO level L2. The anode has an electron affinity EA. L1, L2, and EA satisfy formula (1) below.

−EA−2 eV≦L2≦L1+2 eV (1)

The organic EL element according to this embodiment has an inverted structure and the first hole injection layer is composed of a low LUMO material. Therefore, the luminous life and the design flexibility are improved.

In the organic EL element according to this embodiment, the second hole injection layer is present and therefore the anode is formed on a principal surface with a relatively low roughness. This provides a satisfactory state of an interface of the anode on the cathode side, which makes it difficult to cause electrode separation or the like. Consequently, luminescence unevenness is suppressed.

The organic EL element according to this embodiment includes the first hole injection layer containing a first organic material between the emitting layer and the anode, and thus a portion that allows carrier injection is sufficiently ensured. Furthermore, the organic EL element includes the second hole injection layer containing a second organic material between the first hole injection layer and the anode, the second organic material having a LUMO level L2 satisfying the formula (1), and thus the transport path of generated carriers is ensured. Therefore, in the organic EL element according to this embodiment, a portion that allows efficient carrier injection is sufficiently ensured, which suppresses an increase in the driving voltage.

In the organic EL element according to the above embodiment of the present disclosure, the first organic material may be the same as the second organic material, the second hole injection layer may further contain a third organic material having a flatness lower than those of the first organic material and the second organic material, and a volume ratio of the first organic material in the first hole injection layer may be higher than a volume ratio of the second organic material in the second hole injection layer. In the organic EL element according to this embodiment, the manufacturing process is efficiently performed, the luminous life is increased, and the driving voltage is decreased.

In the organic EL element according to the above embodiment of the present disclosure, the third organic material may have a hole mobility of 1×10⁻² cm²/Vs or less and an electron mobility of 1×10⁻² cm²/Vs or less when an electric field of 1×10⁴ V/cm or more and 1×10⁶ V/cm or less is applied. In the organic EL element according to this embodiment, the second hole injection layer contains the third organic material having a molecular structure with a sufficiently low flatness, and thus the luminescence unevenness is further suppressed.

In the organic EL element according to the above embodiment of the present disclosure, the first organic material may be different from the second organic material. Furthermore, in the organic EL element according to the above embodiment of the present disclosure, the second organic material may have a hole mobility of 1×10⁻² cm²/Vs or less and an electron mobility of 1×10⁻² cm²/Vs or less when an electric field of 1×10⁴ V/cm or more and 1×10⁶ V/cm or less is applied. In the organic EL element according to this embodiment, the second hole injection layer contains the second organic material having a molecular structure with a sufficiently low flatness, and thus the luminescence unevenness is further suppressed.

In the organic EL element according to the above embodiment of the present disclosure, the second hole injection layer may further contain a third organic material, and the third organic material may have a hole mobility of 1×10⁻² cm²/Vs or less and an electron mobility of 1×10⁻² cm²/Vs or less when an electric field of 1×10⁴ V/cm or more and 1×10⁶ V/cm or less is applied. In the organic EL element according to this embodiment, the second hole injection layer contains the third organic material having a molecular structure with a sufficiently low flatness, and thus the luminescence unevenness is further suppressed.

In the organic EL element according to the above embodiment of the present disclosure, the first organic material may be an azatriphenylene derivative represented by chemical formula below.

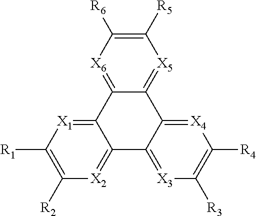

Herein, R₁ to R₆ in the chemical formula each independently represent a substituent selected from hydrogen, a halogen, a hydroxyl group, an amino group, an arylamino group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxyl group having 20 or less carbon atoms, a substituted or unsubstituted aryl group having 30 or less carbon atoms, a substituted or unsubstituted heterocyclic group having 30 or less carbon atoms, a nitrile group, a cyano group, a nitro group, and a silyl group. Adjacent Rₘ (m=1 to 6) may be bonded to each other through a ring structure. X₁ to X₆ in the chemical formula each independently represent a carbon atom or a nitrogen atom.

In the organic EL element according to this embodiment, an azatriphenylene derivative which has been used as a low LUMO material is employed to further stabilize the hole injection function.

In the organic EL element according to the above embodiment of the present disclosure, the first organic material may be 1,4,5,8,9,12-hexaazatriphenylene-2,3,6,7,10,11-hexacarbonitrile (HAT-CN). The second organic material may be HAT-CN. The third organic material may be N,N′-diphenyl-N,N′-bis(1-naphthyl)benzidine (NPB). According to this embodiment, the anode is formed on a principal surface with a relatively low roughness and an interface of the anode on the cathode side is brought into a good state. Consequently, luminescence unevenness is suppressed.

In the organic EL element according to the above embodiment of the present disclosure, a content of the second organic material in the second hole injection layer may be 15 vol % or more. In the organic EL element according to this embodiment, an increase in the driving voltage is sufficiently suppressed.

In the organic EL element according to the above embodiment of the present disclosure, when the first hole injection layer has a thickness of T nm, the second hole injection layer may have a thickness of 0.06×T² nm or more. In the organic EL element according to this embodiment, the second hole injection layer has such a thickness that the rugged geometry of the principal surface of the first hole injection layer on the anode side is sufficiently planarized. This further suppresses the luminescence unevenness.

In the organic EL element according to the above embodiment of the present disclosure, T may be 30 or less. In the organic EL element according to this embodiment, the number of intermolecular barriers in the first hole injection layer is limited. This further suppresses an increase in the driving voltage.

In the organic EL element according to the above embodiment of the present disclosure, a content of the third organic material in the second hole injection layer may be 50 vol % or more. In the organic EL element according to this embodiment, the luminescence unevenness is sufficiently suppressed.

The organic EL element according to the above embodiment of the present disclosure may further include a hole transport layer containing a fourth organic material, the hole transport layer being disposed between the emitting layer and the first hole injection layer. When the fourth organic material has a HOMO level H4, a difference between L1 and H4 may be within 2 eV. In the organic EL element according to this embodiment, holes are smoothly generated, which results in a further increase in the luminous life due to use of a low LUMO material for the hole injection layer.

The organic EL element according to the above embodiment of the present disclosure may further include a hole transport layer containing the third organic material, the hole transport layer being disposed between the emitting layer and the first hole injection layer. When the third organic material has a HOMO level H3, a difference between L1 and H3 may be within 2 eV. In the organic EL element according to this embodiment, the manufacturing process is efficiently performed.

In the organic EL element according to the above embodiment of the present disclosure, the anode is mainly composed of an alloy of magnesium and silver. In the organic EL element according to this embodiment, the driving voltage is further decreased.

An organic EL display panel according to another embodiment of the present disclosure includes the organic EL element according to the above embodiment. In the organic EL display panel according to this embodiment, the displaying quality and reliability are high, electric power savings are achieved, and the structure is simplified. Even when an n-type TFT element is used, an increase in the luminance variation is suppressed, which is advantageous for achieving a large screen.

An organic EL display device according to still another embodiment of the present disclosure includes the organic EL display panel according to the above embodiment. In the organic EL display device according to this embodiment, high performance can be achieved.

A method for manufacturing an organic EL element according to still yet another embodiment includes forming a substrate, a cathode, an emitting layer, a first hole injection layer containing a first organic material whose LUMO level is −4 eV or less, a second hole injection layer, and an anode in that order. The second hole injection layer is formed so that, assuming that the first organic material has a LUMO level L1 and the anode has an electron affinity EA, the second hole injection layer contains a second organic material whose LUMO level L2 satisfies formula (2) below and so that a roughness of a principal surface of the second hole injection layer on the side of the anode is smaller than a roughness of a principal surface of the first hole injection layer on the side of the second hole injection layer.

−EA−2 eV≦L2≦L1+2 eV (2)

The method for manufacturing an organic EL element according to this embodiment provide an organic EL element in which the luminescence unevenness and an increase in the driving voltage are suppressed.

### First Embodiment

Hereafter, an organic EL element 100 according to a first embodiment of the present disclosure will be described with reference to the attached drawings.

### 1. Structure of Organic EL Element 100

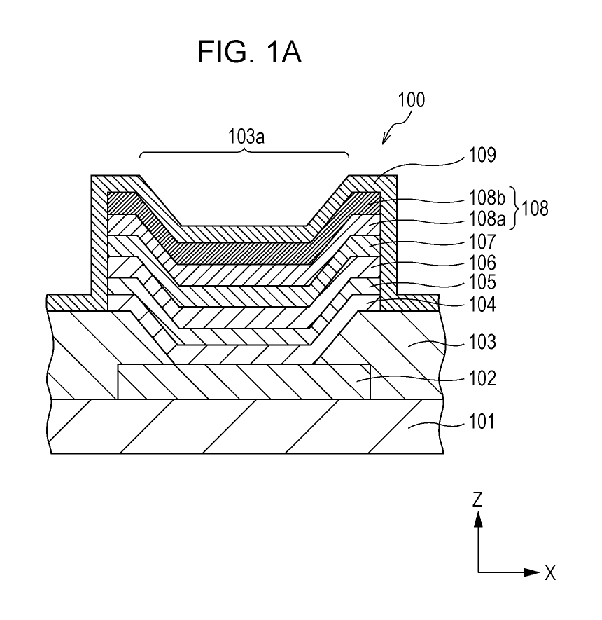

A structure of the organic EL element 100 according to this embodiment will be described with reference to FIG. 1A. FIG. 1A is a schematic sectional view showing the organic EL element 100.

The organic EL element 100 is a luminescence element that uses the phenomenon of electroluminescence of an organic material and is formed in an opening 103a of a bank 103 formed on a substrate 101. The organic EL element 100 has an inverted structure in which a cathode 102, an electron injection layer 104, an electron transport layer 105, an emitting layer 106, a hole transport layer 107, a hole injection layer 108, and an anode 109 are formed on the substrate 101 in that order.

In FIG. 1A, each functional layer is formed so as to extend from the opening 103a to a portion of a principal surface of the bank 103, but the structure of the organic EL element 100 is not limited thereto. Each functional layer may be formed so that a part or an entirety of each functional layer is present within an opening surface of the bank 103.

### (a) Substrate 101

The substrate 101 includes a base material, a TFT layer formed on the base material, and an interlayer insulating layer formed on the base material and the TFT layer. However, these components are not directly related to the description of this embodiment and thus are not illustrated in FIG. 1A.

The base material, is a flat-shaped supporting member of the organic EL element 100. The TFT layer has a multilayer structure including an electrode, a semiconductor layer, and an insulating layer. In the TFT layer, for example, a TFT element, a wiring line, and a capacitor are formed, which constitute a circuit for driving the organic EL element 100 in response to electric signals from an external circuit. The interlayer insulating layer is used to planarize the rugged geometry caused by the TFT layer and to, when required, electrically insulate the circuit of the TFT layer, the organic EL element, and the like.

### (b) Cathode 102

The cathode 102 is connected to the TFT layer through the wiring line and supplies electrons to the emitting layer 106 in accordance with electric power supplied. The cathode 102 has a flat shape. However, for example, when the cathode 102 is connected to the TFT layer through, a contact hole made in the interlayer insulating layer, the cathode 102 has an rugged portion that follows the contact hole.

### (c) Bank 103

The bank 103 is used to define the luminescent area of the organic EL element 100 and to prevent a circuit from shorting out. When each functional layer is formed by a dry process such as vacuum vapor deposition, the bank 103 functions as a base for supporting a mask. When each functional layer is formed by a wet process such as coating or printing, the bank 103 functions as a wall for controlling the flow of ink.

### (d) Electron Injection Layer 104

The electron injection layer 101 facilitates the injection of electrons from the cathode 102 into the emitting layer 106 by reducing the energy barrier during the injection of electrons into the cathode 102. Therefore, the electron injection layer 104 may be composed of a material whose electron affinity is lower than or equal to the ionization energy of the cathode 102 and higher than or equal to the absolute value of the LUMO level of the emitting layer 106.

### (e) Electron Transport Layer 105

The electron transport layer 105 facilitates the transport of electrons to the emitting layer 106, the electrons being injected from the cathode 102 into the electron injection layer 104. Therefore, the electron transport layer 105 is may be composed of a material whose electron affinity is close to the electron affinity of the electron injection layer 104 and the absolute value of the LUMO level of the emitting layer 106 and which has a high electron mobility.

### (f) Emitting Layer 106

The emitting layer 106 is a layer composed of an organic compound and converts electric energy into light as a result of transition of an organic compound excited by recombination of carriers (holes and electrons) to a base state. In the organic EL element 100, the emission color is not particularly limited. To obtain a desired emission color, an organic material that directly emits light having a desired, color by the transition may be used, for the emitting layer 106. Alternatively, an organic material that emits light having a color other than a desired color may be used for the emitting layer 106 and the light may be converted into light having a desired color with a wavelength conversion material.

### (g) Hole Transport Layer 107

The hole transport layer 107 facilitates the transport of holes to the emitting layer 106, the holes being injected from the hole injection layer 108. Therefore, the hole transport layer 107 may be composed of an organic material having a high hole mobility and a HOMO level close to the HOMO level of the emitting layer 106.

### (h) Hole Injection Layer 108

In the organic EL element 100 according to this embodiment, the hole injection layer 108 includes a first hole injection layer 108a formed on the hole transport layer 107 and a second hole injection layer 108b formed on the first hole injection layer 108a.

The first hole injection, layer 108a is used to inject holes into the hole transport layer 107. This is achieved by using a first organic material A having a LUMO level of −4 eV or less for the first hole injection layer 108a. That is, holes are injected from the hole injection layer 108a into the hole transport layer 107 by extracting electrons from the HOMO (typically, the energy level is about −5 eV to −6 eV) of the hole transport layer 107 to the LUMO of the first hole injection layer 108a through voltage application.

The second hole injection layer 108b is used to transport electrons to the anode 109, the electrons being extracted from the hole transport layer 107 to the first hole injection layer 108a. This is achieved by using, for the second hole injection layer 108b, a second organic material B having a LUMO level close to the LUMO level of the first hole injection layer 108a and having an absolute value of the LUMO level close to the electron affinity of the anode 109.

The second hole injection layer 108b also has an upper-surface roughness smaller than the upper surface roughness of the first hole injection layer 108a and thus is used to planarize the upper surface of the first hole injection layer 108a. To decrease the upper surface roughness, the second hole injection layer 108b may contain, for example, a third organic material C having a molecular structure with a low flatness. Herein, the second hole injection layer 108b is a mixed layer containing the second organic material B and the third organic material C.

### (i) Anode 109

In the organic EL element 100, the anode 109 functions as a wiring line that receives and conducts the electrons transported from the second hole injection layer 108b. Therefore, the anode 109 in the organic EL element 100 does not necessarily have a high work function or a stable hole injection function (a stable interface with an organic material) unlike typical organic EL elements.

### 2. Material for Each Layer

The materials for the layers constituting the organic EL element 100 will be exemplified below. The materials used in the organic EL element 100 are not limited to the following materials, and materials having the same function may also be used.

### (a) Substrate 101

The base material may be an electrically insulating material or a semiconductor material such as silicon. The base material may also be, for example, a metal material, such as stainless steel, coated with an electrically insulating material. Examples of the electrically insulating material include alkali-free glass, soda glass, nonfluorescent glass, phosphoric-acid based glass, borate glass, quartz, acrylic resin, styrene resin, polycarbonate resin, epoxy resin, polyethylene resin, polyester resin, polyimide resin, silicone resin, and alumina.

The semiconductor layer in the TFT layer may be composed of, for example, silicon (e.g., amorphous or polycrystalline), an oxide semiconductor such as indium-zinc-gallium oxide, or an organic semiconductor such as a heteroaromatic compound. The electrode and wiring line in the TFT layer may be composed of, for example, a conductive metal or carbon nanotube. The insulating layer in the TFT layer may be composed of, for example, silicon nitride, silicon, oxide, silicon oxynitride, alumina, acrylic resin, polyimide resin, siloxane resin, or phenolic resin.

The interlayer insulating layer may be composed of an electrically insulating material that can be patterned, such as alumina, acrylic resin, polyimide resin, siloxane resin, or phenolic resin.

### (b) Cathode 102

The cathode 102 may be composed of a conductive material. Examples of the conductive material include metals such as aluminum, silvery molybdenum, tungsten, titanium, chromium, nickel, and zinc; alloys such as neodymium-aluminum, gold-aluminum, and magnesium-silver; and conductive oxides such as indium tin oxide (ITO) and indium zinc oxide (IZO). The cathode 102 may have a multilayer structure obtained by stacking these materials.

When the organic EL element 100 is a top emission type organic EL element, the cathode 102 may be preferably composed, of a light reflective material. When the organic EL element 100 is a bottom emission type organic EL element, the cathode 102 may be composed of a light transmissive material.

### (c) Bank 103

The bank 103 may be composed, of an electrically insulating material that can be patterned. For example, materials exemplified as the material for the interlayer insulating layer can be used. The bank 103 may be composed of a material that has resistance to organic solvents and that does not excessively deform or metamorphose through an etching treatment or a baking treatment. When functional layers are formed by a wet process, the surface of the bank 103 may be treated with fluorine to impart liquid repellency to the bank 103.

### (d) Electron Injection Layer 104

The electron injection layer 104 may be composed of a material having an appropriate electron affinity as described above. Specific examples of the material include low work function metals such as lithium, barium, calcium, potassium, cesium, sodium, and rubidium; low work function metal salts such as lithium fluoride and sodium fluoride; and low work function metal oxides such as barium oxide. The electron injection layer 104 may also be composed of a material obtained by dispersing, for example, the low work function metal, the low work function metal salt, or the low work function metal oxide in an electron-transporting organic material (for example, nitro-substituted fluorenone derivative, thiopyran dioxide derivative, diphenoquinone derivative, perylenetetracarboxyl derivative, anthraquinodimethane derivative, fluorenylidenemethane derivative, anthrone derivative, oxadiazole derivative, perinone derivative, quinoline complex derivative, phosphorus oxide derivative, triazole derivative, triazine derivative, silole derivative, dimesitylboron derivative, or triarylboron derivative).

### (e) Electron Transport Layer 105

The electron transport layer 105 may be composed of a material having an appropriate electron affinity and a high electron mobility as described above. Specific examples of the material include nitro-substituted fluorenone derivatives, thiopyran dioxide derivatives, diphenoquinone derivatives, perylenetetracarboxyl derivatives, anthraquinodimethane derivatives, fluorenylidenemethane derivatives, anthrone derivatives, oxadiazole derivatives, perinone derivatives, quinoline complex derivatives fall of which are described in Japanese Unexamined Patent Application Publication No. 5-163488), phosphorus oxide derivatives, triazole derivatives, triazine derivatives, silole derivatives, dimesitylboron derivatives, and triarylboron derivatives.

The electron transport layer 105 may be composed of a material that forms a satisfactory interface with the emitting layer 106 to facilitate the interlayer movement of electrons. Thus, an organic material may be used, but the material is not limited thereto. When the electron transport layer 105 is composed of a material having a low hole mobility, the passage of carriers that do not contribute to light emission is suppressed, which improve the luminous efficiency.

### (f) Emitting Layer 106

The emitting layer 106 may be composed of an organic material that emits light by the phenomenon of electroluminescence. Specific examples of the organic material include publicly known fluorescent materials and phosphorescent light emitting materials. Examples of the fluorescent materials include oxinoid compounds, perylene compounds, coumarin compounds, azacoumarin compounds, oxazole compounds, oxadiazole compounds, perinone compounds, pyrrolo-pyrrole compounds, naphthalene compounds, anthracene compounds, fluorene compounds, fluoranthene compounds, tetracene compounds, pyrene compounds, coronene compounds, quinolone compounds, azaquinolone compounds, pyrazolone derivatives, pyrazolone derivatives, rhodamine compounds, chrysene compounds, phenanthrene compounds, cyclopentadiene compounds, stilbene compounds, diphenylquinone compounds, styryl compounds, butadiene compounds, dicyanomethylene pyran compounds, dicyanomethylene thiopyran compounds, fluorescein compounds, pyrylium compounds, thiapyrylium compounds, selenapyrylium compounds, telluropyrylium compounds, aromatic aldadiene compounds, oligophenylene compounds, thioxanthene compounds, cyanine compounds, acridine compounds, metal complexes of 8-hydroxyquinoline compounds, metal complexes of 2-bipyridine compounds, complexes of a Schiff base and a group three metal, metal complexes of oxine, and rare earth metal complexes (all of which are described in Japanese Unexamined Patent Application Publication No. 5-163488).

Furthermore, for example, the emitting layer 106 may be a mixed layer containing the material for the electron transport layer 105 or the hole transport layer 107 as a host and the fluorescent material or the phosphorescent light emitting material as a dopant.

### (g) Hole Transport Layer 107

The hole transport layer 107 may be composed of a material having an appropriate HOMO level and a high hole mobility as described above. Specific examples of the material include triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, stilbene derivatives, porphyrin compounds, aromatic tertiary amine compounds, styrylamine compounds, butadiene compounds, polystyrene derivatives, triphenylmethane derivatives, and tetraphenylbenzene derivatives (all of which are described in Japanese Unexamined Patent Application Publication No. 5-163488).

As described below, the hole transport layer 107 may be composed of the same material as a hole transport material, which is a specific example of the third organic material C.

### (h) Hole Injection Layer 108

The first hole injection layer 108a may be composed of the first organic material A having a LUMO level of −4 eV or less as described above. The first organic material A is specifically an azatriphenylene derivative represented by chemical formula below.

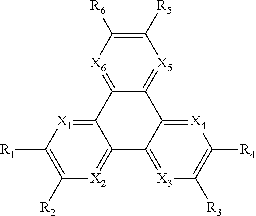

Herein, R₁ to R₆ in the chemical formula each independently represent a substituent selected from hydrogen, a halogen, a hydroxyl group, an amino group, an arylamino group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxyl group having 20 or less carbon atoms, a substituted or unsubstituted aryl group having 30 or less carbon atoms, a substituted or unsubstituted heterocyclic group having 30 or less carbon atoms, a nitrite group, a cyano group, a nitro group, and a silyl group. Adjacent Rₘ (m=1 to 6) may be bonded to each other through a ring structure. X₁ to X₆ in the chemical formula each independently represent a carbon atom or a nitrogen (N) atom.

The azatriphenylene derivative is described in many documents as a low LUMO material used for a hole injection, layer (e.g., refer to Japanese Unexamined Patent Application Publication (Translation of PCT Application) Nos. 2007-533073 and 2003-519432). Therefore, when the first organic material A is an azatriphenylene derivative, the hole injection function of the organic EL element 100 is further stabilized.

The second hole injection layer 108b contains a second organic material B having a LUMO level close to the LUMO level of the first hole injection layer 108a and having an absolute value of the LUMO level close to the electron affinity of the anode 109. More specifically, when the LUMO level of the first organic material A is L1 and the electron affinity of the anode 109 is ETA, the LUMO level L2 of the second organic material B satisfies formula (1) below.

−EA−2 eV≦L2≦L1+2 eV (1)

A specific selection method of the second organic material B that satisfies the above condition is, for example, to use the same material as the first organic material A.

Other materials contained in the second hole injection layer 108b are not particularly limited as long as the upper surface roughness of the second hole injection layer 108b is smaller than the upper surface roughness of the first hole injection layer 108a.

In this case, when the second organic material B is the same as the first organic material A as described above, the second hole injection layer 108b contains, in addition to the second organic material B, the third organic material C having a flatness lower than that of the second organic material B. The volume ratio of the first organic material A in the first hole injection layer 108a is higher than the volume ratio of the second organic material B in the second hole injection layer 108b. The third organic material C may be selected so as to have a hole mobility of 1×10⁻² cm²/Vs or less and an electron mobility of 1×10⁻² cm²/Vs or less when an electric field of 1×10⁴ V/cm or more and 1×10⁶ V/cm or less is applied.

When the second organic material B is different from the first organic material A, the first organic material A and the second organic material B may be freely selected as long as the formula (1) is satisfied and the upper surface roughness of the second hole injection layer 108b is smaller than the upper surface roughness of the first hole injection layer 108a. For example, the second organic material B may be a material having a hole mobility of 1×10⁻² cm²/Vs or less and an electron mobility of 1×10⁻² cm²/Vs or less when an electric field of 1×10⁴ V/cm or more and 1×10⁶ V/cm or less is applied.

Furthermore, when the second organic material B is different from the first organic material A, the second hole injection layer 108b may further contain a third organic material C with a low flatness. As in the conditions described above, the third organic material C with a low flatness may be a material having a hole mobility of 1×10⁻² cm²/Vs or less and an electron mobility of 1×10⁻² cm²/Vs or less when an electric field of 1×10⁴ V/cm or more and 1×10⁶ V/cm or less is applied. In this case, the third organic material C is further contained, whereby the upper surface roughness of the second hole injection layer 108b can be further made smaller than the upper surface roughness of the first hole injection layer 108a.

In general, the carrier mobility increases as the flatness of a molecular structure increases. Therefore, the flatness of a molecular structure decreases as the carrier mobility decreases. Consequently, the material having the above-described carrier mobility has a molecular structure with a sufficiently low flatness. Therefore, the luminescence unevenness of the organic EL element 100 is further suppressed.

The third organic material C may be a hole transport material or an electron transport material. For example, the materials for the electron transport layer 105 or the hole transport layer 107 may be used.

Specific examples of the hole transport material used as the third organic material C include NPB, triphenylamine derivatives (TPD, α-NPD, β-NPB, MeO-TPD, and TAPC), phenylamine tetramers (TPTE), starburst-type triphenylamine derivatives (m-MTDADA, NATA, 1-TNATA, and 2-TNATA), spiro-type triphenylamine derivatives (spiro-TPD, spiro-NPD, and spiro-TAD), titanium oxide phthalocyanine (TiOPc), α-sexithiophene (α-6T), carbazole derivatives (MCP, CBP, and TCTA), and triphenylsilyl derivatives (UGH2 and UGH3).

Specific examples of the electron transport material used as the third organic material C include quinolinol complexes (Alq₃, BAlq, and Liq), phenanthroline derivatives (BCP and BPhen), phosphorus oxide derivatives (POPy2), oxadiazole derivatives (PBD), oxadiazole dimers (OXD-7), starburst oxadiazole (TPOB), spiro-type oxadiazole derivatives, triazole derivatives (TAZ), triazine derivatives (TRZ, DPT, and MPT), silole derivatives (PyPySPyPy), dimesitylboron derivatives (BMB), and triarylboron derivatives (TPhB).

The second hole injection layer 108b may contain a material other than the second organic material B and the third organic material C.

### (i) Anode 109

The anode 109 may be composed of a conductive material. In the organic EL element 100, as described above, the anode 109 does not necessarily have a high work function and a stable hole injection function, and thus a wide range of materials may be selected. Specifically, the materials for the cathode 102 may be used. When the organic EL element 100 is a top emission type organic EL element, the anode 109 may be composed of a light transmissive material. When the organic EL element 100 is a bottom emission type organic EL element, the anode 109 may be composed of a light reflective material.

### 3. Method for Manufacturing Organic EL Element 100

A method for manufacturing the organic EL element 100 will be described below. The manufacturing method below is merely an example, and the method for manufacturing the organic EL element 100 is not limited thereto. In particular, in the following description, a dry process that uses vacuum vapor deposition is mainly employed, but the process is not limited thereto. For example, a wet process such as an ink jet method, a dispenser method, a nozzle coating method, an intaglio printing method, or a letterpress printing method may be employed. The dry process and the wet process may also be combined with each other. Alternatively, a transfer method with which an organic material is transferred from a donor substrate may be employed.

### (a) Step of Preparing Substrate

A substrate 101 is prepared. Specifically, for example, a thin film is formed on a base material by a reactive sputtering method, a chemical vapor deposition (CVD) method, a spin coating method, or the like. The thin film is patterned by a photolithography method or the like to form a TFT layer and an interlayer insulating layer. If necessary, for example, a plasma treatment, ion implantation, and baking may be performed.

### (b) Step of Forming Cathode

Next, a cathode 102 is formed on the substrate 101. Specifically, for example, the substrate 101 is placed in a chamber of a sputtering apparatus. A predetermined sputtering gas is introduced into the chamber and a metal material for a cathode 102 is formed by a reactive sputtering method. The metal material is then patterned by wet etching to form a cathode 102. Note that the cathode 102 may be formed by vacuum vapor deposition or the like.

### (c) Step of Forming Bank

Next, a bank 103 is formed on the substrate 101 on which the cathode 102 has been formed. Specifically, for example, a photosensitive material or a material containing a fluorine resin or an acrylic resin is uniformly applied onto the substrate 101 on which the cathode 102 has been formed. The material, is prebaked to form a film composed of a material for a bank 103. The substrate 101 on which the film, has been formed is exposed through a mask having a pattern corresponding to an opening 103a. Subsequently, an uncured portion is dissolved with a developing solution and washing is performed with pure water to form a bank 103 having an opening 103a.

As described above, the formed bank 103 may be subjected to a surface treatment using an alkaline solution, water, an organic solvent, or the like or may be subjected to a plasma treatment in order to adjust the contact angle on a surface of the bank 103 and impart the water-repellent property to the surface.

### (d) Step of Forming Functional Layers

Next, an electron injection layer 104 is formed in the opening 103a. Specifically, for example, a metal mask having an opening corresponding to the opening 103a is placed, on the bank 103. In this state, a film composed of a material for an electron injection layer 104 is formed, in the opening of the metal mask by vacuum vapor deposition, and thus an electron injection layer 104 is formed. Herein, when the electron injection layer 104 is also formed on a principal surface of the bank 103 by using a metal mask having an opening larger than the opening 103a as shown in FIG. 1A, the exposure of the cathode 102 which may cause a short circuit can be prevented even if the position of the metal mask placed or the position of the opening is misaligned to some extent.

Similarly, an electron transport layer 105, an emitting layer 106, a hole transport layer 107, a first hole injection layer 108a, and a second hole injection layer 108b are formed by vacuum vapor deposition that uses a metal mask in that order in the opening 103a in which, the electron injection layer 104 has been formed.

When a mixed layer containing a plurality of materials, such as the organic emitting layer 106 or the second hole injection layer 108b, is formed, a method (codeposition) in which deposition is performed using two deposition sources at the same time may be employed. Furthermore, each functional layer may be formed so as to completely cover the corresponding underlying layer within the side surface of the bank 103. In this case, the formation of the short circuit path of carriers can be prevented.

### (e) Step of Forming Anode 109

Next, an anode 109 is formed on the second hole injection layer 108b. An anode 109 may be formed by, for example, vacuum vapor deposition. By forming the anode 109 so as to cover a portion of the principal surface of the bank 103 on which each functional layer is not formed, the manufacturing process can be simplified and the misalignment can be prevented.

### 4. Effects

### (a) Structure of Organic EL Element 100

The organic EL element 100 is an organic EL element including the substrate 101, the cathode 102, the emitting layer 106, the first hole injection layer 108a containing the first organic material whose LUMO level is −4 eV or less, and the anode 109 disposed in that order. The organic EL element 100 further includes the second hole injection layer 108b containing the second organic material B and disposed between the first hole injection layer 108a and the anode 109. Furthermore, the roughness of the upper surface (the principal surface on the anode side) of the second hole injection layer 108b is smaller than the roughness of the upper surface (the principal surface on the anode side) of the first hole injection layer 108a. The first organic material A has a LUMO level L1. The second organic material B has a LUMO level L2. The anode 109 has an electron affinity EA. L1, L2, and EA satisfy formula (1) below.

−EA−2 eV≦L2≦L1+2 eV (1)

(b) Effect on Luminescence Unevenness

The organic EL element 100 further includes the second hole injection layer 108b disposed between the first hole injection layer 108a and the anode 109, the upper surface roughness of the second hole injection layer 108b being smaller than the upper surface roughness of the first hole injection layer 108a. Therefore, the anode 109 is formed on the second hole injection layer 108b having a relatively low roughness. The interface between the second hole injection layer 108b and the anode 109 has a satisfactory state, which makes it difficult to cause electrode separation or the like. Thus, in the organic EL element 100, the luminescence unevenness is suppressed.

### (c) Effect on Increase in Driving Voltage

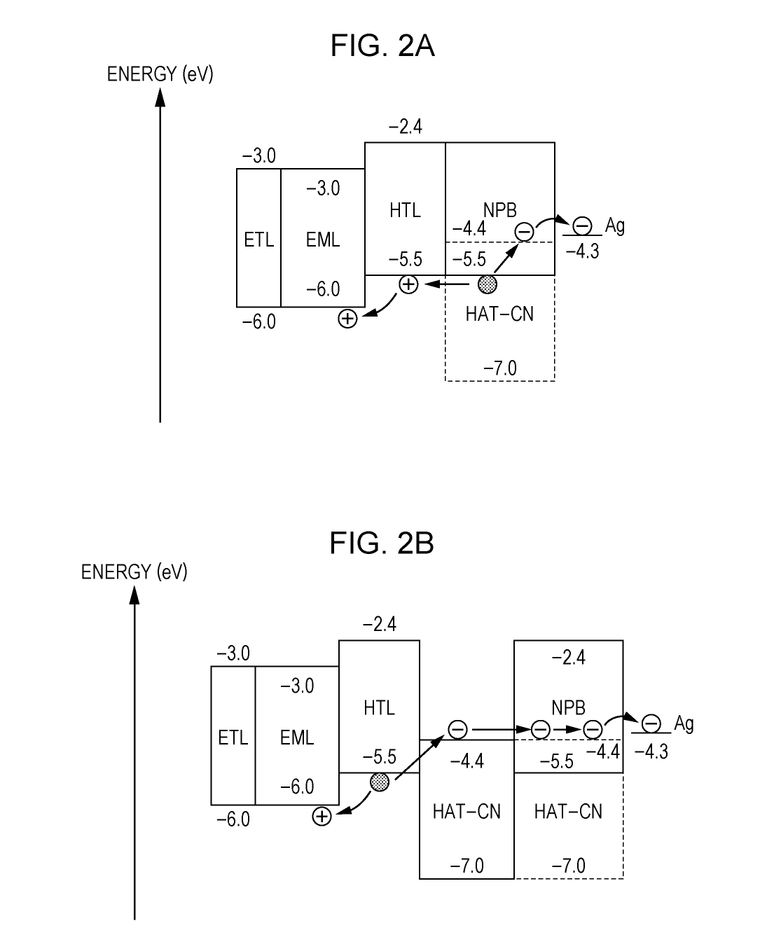

The organic EL element 100 includes the first hole injection layer 108a containing the first organic material A, the first hole injection layer 108a being disposed between the emitting layer 106 and the anode 109. The organic EL element 100 also includes the second hole injection layer 108b disposed between the first hole injection layer 108a and the anode 109, the second hole injection layer 108b containing the second organic material B having a LUMO level L2 within the particular range (the formula (1)). Thus, in the organic EL element 100, an increase in the driving voltage can be suppressed. This effect will be described below in detail with reference to FIGS. 2A and 2B.

FIG. 2A is a schematic view for describing the movement of carriers in the organic EL element 900b. FIG. 2B is a schematic view for describing the movement of carriers in the organic EL element 100. In the drawings, ETL denotes an electron transport layer, EML denotes an emitting layer, and HTL denotes a hole transport layer.

The vertical direction in the drawings indicates the degree of energy level for electrons, and the energy for electrons increases in an upper direction. In the drawings, the upper side of each rectangle indicates a LUMO level of the corresponding functional layer and the lower side of each rectangle indicates a HOMO level of the corresponding functional layer. The numeral is a specific value of each energy level. In the hole injection layer 908b and the hole injection layer 108b, the LUMO level and the HOMO level of HAT-CN are indicated by a dotted line for the purpose of differentiation.

In FIG. 2B, to make the description more specific, the organic EL element 100 has the same structure as the organic EL element 900b except for the hole injection layer 108. Regarding the hole injection layer 108, the first hole injection layer 108a is a HAT-CN single layer and the second hole injection layer 108b is a mixed, layer of NPB and HAT-CN. Both the first hole injection layer 108a and the second hole injection layer 108b have a thickness of 10 nm. In other words, the first organic material A and the second organic material B are HAT-CN and the third organic material C is NPB. This structure does not limit the organic EL element 100.

In the organic EL element including a hole injection layer composed of a low LUMO material, the LUMO level of a hole injection layer is generally closer to the HOMO level of a hole transport material in the adjacent hole transport layer (or an emitting material in an emitting layer) than the HOMO level of the hole injection layer. Through voltage application, electrons are extracted from the HOMO of the hole transport layer (or the emitting layer) to the LUMO of the hole injection layer. Consequently, holes are generated at the HOMO of the hole transport layer (or the emitting layer) from which electrons have been extracted. Carrier injection is caused in this manner.

As a result of the voltage application, the holes generated at the HOMO of the hole transport layer are transported to the emitting layer and the electrons extracted to the LUMO of the hole injection layer are transported to the anode, whereby an electric current flows through the organic EL element.

Since the organic EL element 900b includes the hole injection layer 908b containing NPB serving as a hole transport material, the carrier injection is caused in the hole injection layer 908b as shown in FIG. 2a. Specifically, as a result of the voltage application, electrons at the HOMO (−5.5 eV) of NPB in the hole injection layer 908b are extracted to the LUMO (−4.4 eV) of HAT-CN in the hole injection layer 908b. Holes are generated at the HOMO of NPB in the hole injection layer 908b from which, the electrons have been extracted.

The extracted electrons are transported to the Fermi level (−4.3 eV) of Ag, which is the anode 109, through the LUMO of HAT-CN by an applied voltage. The generated holes are transported to the HOMO (−5.5 eV) of the hole transport layer 107 through the HOMO of NPB by the applied voltage.

However, NPB and HAT-CN are dispersed in the hole injection layer 908b. Therefore, the combination of NPB and HAT-CN that allows efficient carrier injection is limited compared with the organic EL element 900a in which a NPB single layer and a HAT-CN single layer are adjacent to each other.

For example, simply, the number of portions in which NPB and HAT-CN contact each other in the direction of a voltage application may be decreased depending on the degree of the dispersion between NPB and HAT-CN. Furthermore, the carrier injection is not always efficiently caused in all the portions in which NPB and HAT-CN contact each other in the direction of a voltage application. For example, in portions in which the transport path of the electrons extracted to the LUMO of HAT-CN to the anode 109 is not provided (e.g., portions surrounded, by NPB on the anode 109 side), the energy barrier for extracting electrons further increases. Similarly, in portions in which the transport path of the holes generated at the HOMO of NPB to the hole transport layer 107 is not provided, the energy barrier for generating holes further increases.

In the organic EL element 900b, such a relative decrease in the combination of NPB and HAT-CN that allows efficient carrier injection increases the driving voltage.

In the organic EL element 100 shown in FIG. 2B, a HAT-CN single layer serving as the first hole injection layer 108a is adjacent to the hole transport layer 107 as in the organic EL element 900a. This provides a sufficient number of portions in which a hole transport material and HAT-CN contact each other in the direction of a voltage application. The electrons extracted to the LUMO of HAT-CN are transported through the LUMO of HAT-CN in the second hole injection layer 108b that contacts some portions of the first hole injection layer 108a, whereby the transport path to the anode 109 is provided. Since the hole transport layer 107 originally has high hole transportability to the emitting layer 106, the transport path of the holes generated at the HOMO of the hole transport layer 107 is also provided.

This is summarized to be as follows. The organic EL element 100 includes the first hole injection layer 108a containing the first organic material A, the first hole injection layer 108a being disposed between the emitting layer 106 and the anode 109. In the organic EL element 100 having such a structure, a single layer composed of the first organic material A (e.g., HAT-CN) serving as a low LUMO material and the hole transport layer 107 (or the emitting layer 106) are adjacent to each other, which sufficiently provides portions that allow carrier injection.

The organic EL element 100 also includes the second hole injection layer 108b disposed between the first hole injection layer 108a and the anode 109, the second hole injection layer 108b containing the second organic material B having a LUMO level L2 within the particular range (the formula (1)). Thus, the electrons extracted to the first hole injection layer 108a are transported through the LUMO of the second organic material B having a low energy barrier, thereby providing the transport path to the anode 109. The holes generated as a result of the extraction of electrons are transported to the emitting layer 106 directly or through the hole transport layer 107. That is, the transport paths of electrons and holes generated as a result of carrier injection are provided in the organic EL element 100, which allows efficient carrier injection.

In the organic EL element 100, an increase in the driving voltage is suppressed by sufficiently providing portions that allow efficient carrier injection.

The organic EL element 100 includes the second hole injection layer 108b, which is similar to the hole injection layer 908b of the organic EL element 900b, but the second hole injection layer 108b does not considerably affect the increase in the driving voltage. In view of carrier transport, the role of the second hole injection layer 108b is only to transport the electrons extracted, to the LUMO of the first hole injection layer 108a to the anode 109 through the LUMO of the second organic material B (e.g., HAT-CN) as shown in FIG. 2B.

In this regard, to provide the transport path of electrons, the second hole injection layer 103b may contain at least the second organic material B having a LUMO level L2 within a particular range. The second, hole injection layer 108b may contain the third organic material C (e.g., NPB), which is not a low LUMO material. Herein, a decrease in the content of the second organic material B increases the electrical resistivity until the generated electrons are transported to the anode 109, but this influence is not so considerable. Thus, the driving voltage does not markedly increase.

The particular range of the LUMO level L2 is specifically the range described in the formula (1). When L2 is lower than −EA−2 eV, the energy barrier with the anode 109 increases. When the L2 is higher than L1+2 eV, the energy barrier with the first hole injection layer 108a increases. Consequently, the driving voltage may increase.

Accordingly, an increase in the driving voltage is suppressed in the organic EL element 100.

### (d) Other Effects

The organic EL element 100 includes the first hole injection layer 108a composed of the first organic material A serving as a low LUMO material. As described above, holes are generated at the interface between the hole transport layer 107 and the first hole injection layer 103a. Consequently, an interface between the anode 109 and the hole injection layer 108, the interface being generally unstable in organic EL elements, can be removed from the carrier formation process. Therefore, in the organic EL element 100, a low-voltage drive can be stably performed, which increases the luminous life. Moreover, the range of selectivity for the anode material is expanded.

The organic EL element 100 has an inverted structure. Therefore, the luminance variation among pixels is suppressed in the combination with an n-type TFT element suitable for a large display panel as described above.

### 5. Verification with Examples

The organic EL element 100 having the above structure was actually manufactured and the effects were verified. Herein, the organic EL element 900a is regarded as Comparative Example 1 and the organic EL element 900b is regarded as Comparative Example 2. In Comparative Example 1, a HAT-CN single layer was used as the first hole injection layer 103a having a thickness of 10 nm. In Comparative Example 2, a mixed layer of NPB and HAT-CN was used as the first hole injection layer 108a having a thickness of 10 nm.

Examples have the same structure as those of Comparative Examples 1 and 2, except for the hole injection layer 908a and the hole injection layer 908b. In Examples, a HAT-CN single layer was used as the first hole injection layer 108a having a thickness of 10 nm and a mixed layer of NPB and HAT-CN was used as the second hole injection layer 108b having a thickness of 10 nm. That is, the first hole injection layer 108a is the same as the hole injection layer 908a of Comparative Example 1. The second hole injection layer 108b is the same as the hole injection layer 908b of Comparative Example 2.

Examples include Example 1 in which the content of HAT-CN was 15% and Example 2 in which the content of HAT-CM was 35% in order to verify the difference in effects based on the content of HAT-CN in the second hole injection layer 108b.

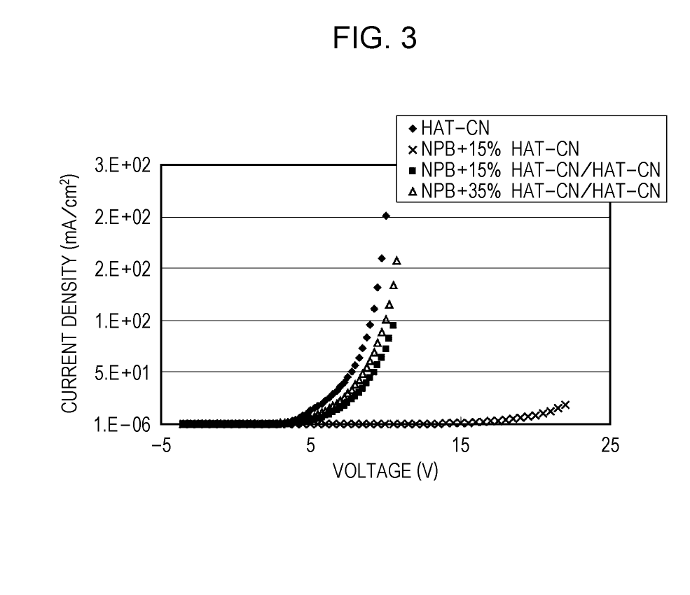

FIG. 3 is a graph showing the relationship between applied voltage (horizontal axis) and current density (vertical axis) in Examples and Comparative Examples. In FIG. 3, plots represented by a solid-black diamond are measurement data in Comparative Example 1, plots represented by X are measurement data in Comparative Example 2, plots represented by a solid-black square are measurement data in Example 1, and plots represented by a solid-white triangle are measurement data in Example 2. In FIG. 3, the measurement data in Comparative Example 2 was obtained when the content of HAT-CN in the hole injection layer 908b was 15%.

As is clear from the graph, an increase in the driving voltage is further suppressed in Examples 1 and 2 than in Comparative Example 2, and Examples 1 and 2 exhibit characteristics close to those of Comparative Example 1. Table shows the structure and the driving voltage (voltage at which the current density exceeds 10 mA/cm²) in Examples and Comparative Examples.

TABLE

| | | Driving |
|---|---|---|
| | Structure of hole injection layer | voltage (V) |
| Comparative | HAT-CN single layer (10 nm) | 4.7 |
| Example 1 | | |
| Comparative | NPB + 15% HAT-CN mixed layer (10 nm) | 20.7 |
| Example 2 | | |
| Example 1 | First hole injection layer: HAT-CN single | |
| | layer (10 nm) | 6.3 |
| | Second hole injection layer: NPB + 15% | |
| | HAT-CN mixed layer (10 nm) | |
| Example 2 | First hole injection layer: HAT-CN single | |
| | layer (10 nm) | 5.5 |
| | Second hole injection layer: NPB + 35% | |
| | HAT-CN mixed layer (10 nm) | |

As is clear from Table, the organic EL element 100 had a sufficiently low driving voltage in accordance with the mechanism described using FIG. 2. It is also confirmed that, in Examples 1 and 2, the luminescence unevenness did not occur. These results demonstrate that desired effects are actually produced by the structure of the organic EL element 100.

It is found from the comparison between Example 1 and Example 2 in Table that the driving voltage increases as the content of the second organic material B in the second hole injection layer 108b decreases. This may be because the current path (LUMO of the second organic material) in the second hole injection layer 108b becomes narrow, which increases the electrical resistivity and thus increases the voltage reduction. Herein, even at the content (15%) in Example 1, the driving voltage is 6.3 V at which an organic EL element can be practically used.

### 6. Supplementary Matter

In the organic EL element 100, the content of the second organic material B in the second hole injection layer 108b may be 15% or more. As described above, the second organic material B is contained to suppress an increase in the driving voltage. As shown in Table, the driving voltage at the content 15% poses no problem. Therefore, in the organic EL element 100 having the above structure, an increase in the driving voltage is sufficiently suppressed.

In the organic EL element 100, when the first hole injection layer 108a has a thickness of T nm, the second hole injection layer 108b may have a thickness of 0.06×T² nm or more.

As analyzed with the AFM images in FIGS. 9A and 9B, when the first hole injection layer 108a has a thickness of T nm, the maximum roughness Rmax of the first, hole injection layer 108a is 0.06×T² nm. That is, the second hole injection layer 108b may have a thickness of 0.06×T² nm or more to planarize the rugged geometry of the upper surface of the first hole injection layer 108a. Therefore, in the organic EL element 100 having the above structure, the luminescence unevenness is further suppressed.

Since the second organic material B has a LUMO level close to that of the first organic material A, an increase in the thickness of the second hole injection layer 108b may cause the rugged geometry due to the second organic material B. When an organic EL element 100 was manufactured in the same manner as in Examples, except that the second hole injection layer 108b had a thickness of 80 nm and the content of the second organic material B (HAT-CN) in the second hole injection layer 108b was 50%, the luminescence unevenness did not occur. Therefore, when the thickness of the second hole injection layer 108b is 80 nm or less, the formation of rugged geometry caused by the thickness of the second hole injection layer 108b is negligible.

In the organic EL element 100, the thickness T of the first hole injection layer 103a may have the thickness of 30 nm or less. A layer composed of an organic material includes a number of molecules therein. The energy barrier generated when carriers move is large between the molecules, and thus the driving voltage is considerably affected by the thickness (number of molecules) of the layer. Therefore, in the organic EL element 100 having the above structure, the thickness of the first hole injection layer 108a (the number of intermolecular barriers in the layer) is limited, which further suppresses an increase in the driving voltage.

In the organic EL element 100, the first organic material A may be the same as the second organic material B. In this structure, the number of types of required materials and facilities can be reduced in the manufacturing of the organic EL element 100. Therefore, in the organic EL element 100 having the above structure, the manufacturing process is efficiently performed. Herein, since the interface between the first hole injection layer 108a and the second hole injection layer 108b is stabilized and electrons are satisfactorily transported, the luminous life of the organic EL element 100 is further increased and an increase in the driving voltage is further suppressed.

In the organic EL element 100, when the second hole injection layer 108b contains the third organic material C, the content of the third organic material C in the second hole injection layer 108b may be 50% or more. The third organic material C is contained to suppress the luminescence unevenness. As shown in FIGS. 11A to 11C, the luminescence unevenness does not occur at the content 50%. Therefore, in the organic EL element 100 having the above structure, the luminescence unevenness is sufficiently suppressed.

In the organic EL element 100, a hole transport layer 107 containing a fourth organic material D is disposed between the emitting layer 106 and the first hole injection layer 108a. When the fourth organic material D has a HOMO level H4, a difference between L1 and H4 may be within 2 eV.

The presence of the hole transport layer 107 having a HOMO level H4 sufficiently close to the LUMO level L1 of the first hole injection layer 108a smoothly causes the generation of carriers (extraction of electrons) between the hole transport layer 107 and the first hole injection layer 108a. It is described in Japanese Unexamined Patent Application Publication (Translation of PCT Application) No. 2007-533073 that when the LUMO level of an organic layer adjacent to a hole transport layer having a HOMO level of −6 eV is −4 eV, that is, when the difference between the LUMO level and the HOMO level is −2 eV, holes are generated (electrons are extracted) by an applied voltage. It is reported in many documents that when the difference between the HOMO level of one of organic layers adjacent to each other and the LUMO level of the other layer is about 1.5 eV, electrons are easily extracted from the HOMO to the LUMO by an applied voltage.

Therefore, in the organic EL element 100 having the above structure, the luminous life is further increased by using a low LUMO material for the hole injection layer 108.

In the organic EL element 100, the third organic material C may be the same as the fourth organic material D. A hole transport layer 107 containing the third organic material C is disposed between the emitting layer 106 and the first hole injection layer 108a. When the third organic material C has a HOMO level H3, a difference between L1 and H3 may be within 2 eV. In this structure, the number of types of required materials and facilities can be reduced in the manufacturing of the organic EL element 100. Therefore, in the organic EL element 100 having the above structure, the manufacturing process is efficiently performed.

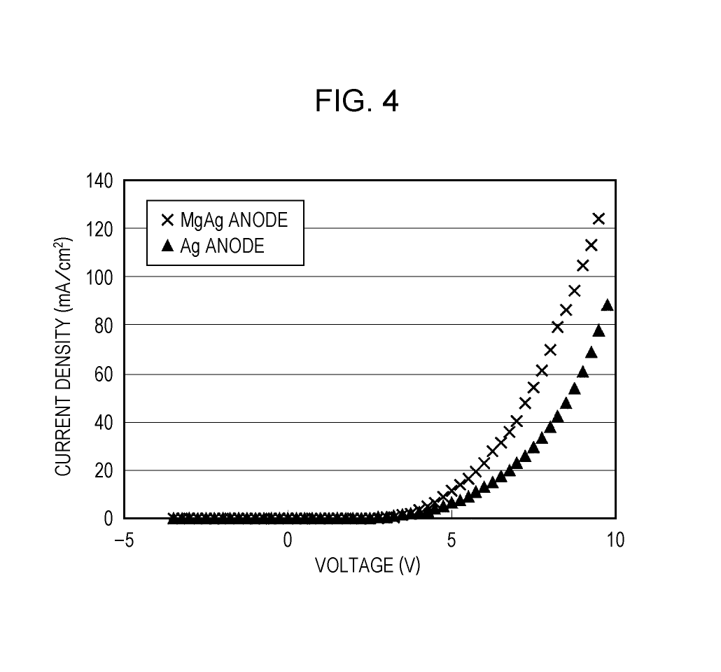

In the organic EL element 100, the anode 109 may be mainly composed of an alloy of magnesium and silver. An effect produced by this structure will be described below with reference to FIG. 4. FIG. 4 is a graph showing the relationship between applied voltage and current density in Examples of the organic EL element 100. Examples used herein include Example 3 which is the same as Example 2 except that the anode 109 is composed of silver and Example 4 which is the same as Example 2 except that the anode 109 is composed of an alloy of magnesium and silver. In FIG. 4, plots represented by a solid-black triangle are measurement data in Example 3 and plots represented by X are measurement data in Example 4.

In Example 4, the manufacturing was performed until the formation of the hole injection layer 108b and then a co-evaporation film composed, of magnesium, and silver was formed by vacuum, vapor deposition so as to have a thickness of 14 nm. Thus, the anode 109 was formed. The ratio of magnesium to silver was magnesium:silver=10:1.

The alloy of magnesium and silver has a work function lower than that of silver. Therefore, in the organic EL element 100, the energy barrier is higher in Example 4 in which the anode 109 is composed of an alloy of magnesium and silver than in Example 3 in which the anode 109 is composed of silver, from the viewpoint of the extraction of electrons from the second hole injection layer 108b. In other words, the driving voltage should increase in general.

However, as shown in FIG. 4, the driving voltage in Example 4 is lower than the driving voltage in Example 3. This is because the alloy of magnesium and silver forms a better interface with the second hole injection layer 108b than silver. In particular, since a magnesium atom is lighter than a silver atom, the damage to the underlying layer during vapor deposition can be reduced. In Example 4, the thickness of the anode 109 was set to be 14 nm, but the same result was confirmed, when the thickness was in the range of 10 nm to 20 nm.

Therefore, in the organic EL element 100 having the above structure, the driving voltage is further suppressed.

### 7. Modified Examples

The organic EL element 100 according to an embodiment of the present disclosure has been described, but the present disclosure is not limited to the embodiment except for its distinctive components. For example, the present disclosure includes an embodiment obtained by subjecting the embodiment to various alterations conceivable by persons skilled in the art and an embodiment realized by freely combining components and functions in the embodiment without departing from the scope of the present disclosure.

Hereafter, a modified example of the organic EL element 100 will be described as an example of such embodiments. The same parts as in the first embodiment are designated by the same reference numerals, and the description thereof is simplified or omitted.

In the first embodiment, the hole injection layer 108 of the organic EL element 100 has a two-layer structure including the first hole injection layer 108a and the second hole injection layer 108b. However, the hole injection layer 108 is not limited thereto and may have a multilayer structure including three or more layers. In this case, the first hole injection layer 108a is formed directly on the hole transport layer 107 and the second hole injection layer 108b may be any layer disposed between the first hole injection layer 108a and the anode 109.

In the first embodiment, the case where the first hole injection layer 108a is composed of only HAT-CN has been described as an example. However, the present disclosure is not limited thereto, and the first hole injection layer 108a may contain other materials in addition to HAT-CN.

In the first embodiment, the functional layers of the organic EL element 100 are the electron injection layer 104, the electron transport layer 105, the emitting layer 106, the hole transport layer 107, and the hole injection layer 108. However, the functional layers are not limited thereto.

For example, some or all of the electron injection layer 104, the electron transport layer 105, and the hole transport layer 107 may be excluded. For example, a blocking layer for improving the luminous efficiency by confining carriers in the emitting layer 106 may be included in addition to the above layers. For example, a single layer may have a plurality of functions provided by the functional layers.

In the first embodiment, the emitting layer 106 is a single layer. However, the emitting layer 106 is not limited thereto and may have a so-called multi-photoemission structure. In this case, a charge generating layer needs to be disposed between a plurality of emitting layers 106. If the first hole injection layer 108a is used as the charge generating layer, the interface between the functional layers is stabilized, which can increase the life of the organic EL element 100.

The organic EL element 100 may also include a sealing layer and a color filter layer below the cathode 102 or above the anode 109.

The sealing layer is formed so as to cover the organic EL element 100. Consequently, moisture, air, and the like can be prevented from entering the organic EL element 100 and the degradation of each functional layer is suppressed. Furthermore, when the sealing layer is composed of a rigid material, the durability of the organic EL element 100 against an external pressure can be improved.

The color filter layer is used to adjust the color of light emitted from the organic EL element 100 to be a color close to a desired color. When the organic EL element 100 is a top emission type organic EL element, the color filter layer is formed above the anode 109. When the organic EL element 100 is a bottom emission type organic EL element, the color filter layer is formed below the cathode 102.

In the first embodiment, the exposed surface of the cathode 102 of the organic EL element 100 has a square shape with a size of 2.3 mm×2.3 mm in Examples and Comparative Examples. However, the exposed surface is not limited thereto. The size and shape of the exposed surface is freely selected. For example, the exposed surface may have a smaller or larger square shape, a rectangular shape, a diamond shape, a polygonal shape, a circular shape, or an elliptical shape.

### Second Embodiment

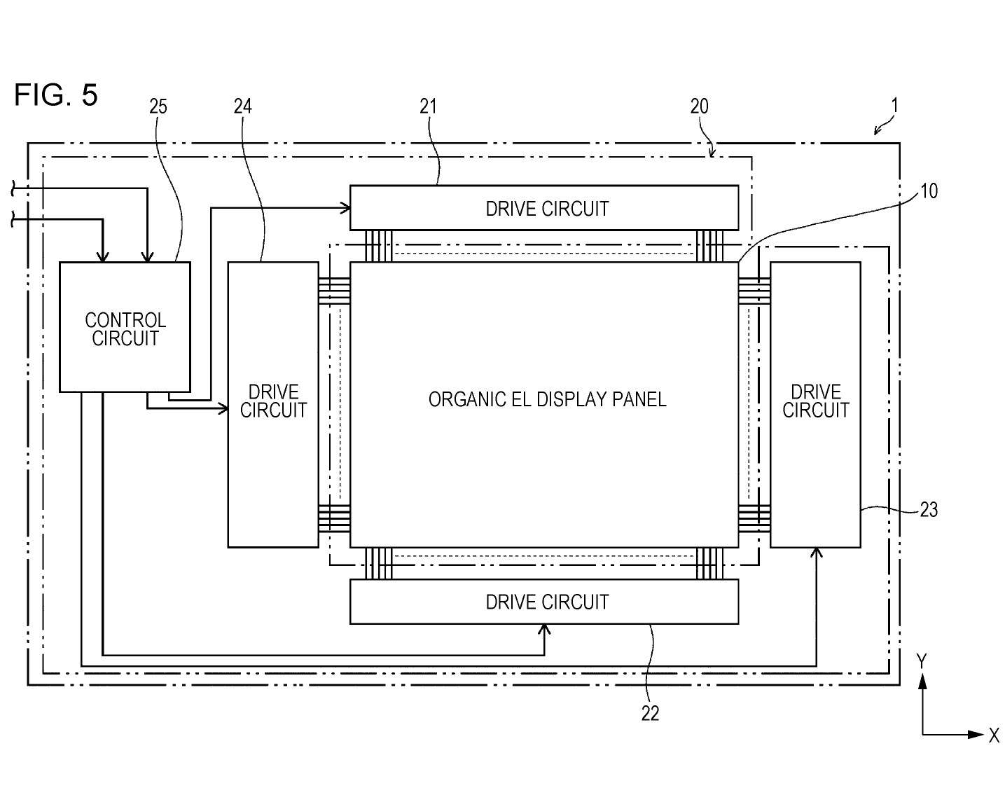

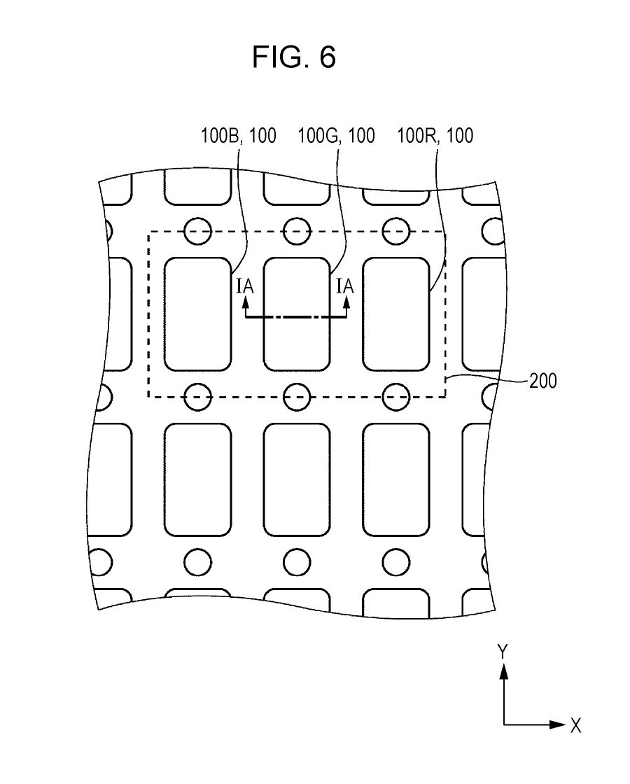

Hereafter, an organic EL display device 1 according to a second embodiment of the present disclosure will be described with reference to FIGS. 5 and 6.

### 1. Structure of Organic EL Display Device 1

FIG. 5 is a block diagram schematically showing a structure of an organic EL display device 1. The organic EL display device 1 includes an organic EL display panel 10 and a drive control unit 20 connected to the organic EL display panel 10. The organic EL display panel 10 is a display panel including the organic EL element 100 according to the first embodiment. The organic EL display panel 10 includes a plurality of the organic EL elements 100 arranged in a matrix. The drive control unit 20 includes four drive circuits 21 to 24 and a control circuit 25. In the organic EL display device 1, the arrangement of the drive control unit 20 for the organic EL display panel 10 is not limited thereto.

In the control circuit 25, video signals are input from the outside and control signals based on the video signals are output to the drive circuits (scanning line drive circuits) 23 and 24 and the drive circuits (signal line drive circuits) 21 and 22.

The drive circuits 23 and 24 are connected to a plurality of scanning lines arranged in an X direction. The drive circuits 23 and 24 are drive circuits for controlling ON and OFF of each switching transistor of the organic EL element 100 according to the first embodiment by outputting scanning signals to the plurality of scanning lines.

The drive circuits 21 and 22 are connected to a plurality of data lines arranged in a Y direction. The drive circuits 21 and 22 are drive circuits for outputting data voltage based on the video signals to the organic EL element 100 according to the first embodiment.

The organic EL display panel 10 includes a plurality of organic EL elements 100 arranged in a matrix in X and Y directions and displays an image in response to the video signals input to the organic EL display device 1 from the outside.

### 2. Structure of Organic EL Display Panel 10

FIG. 6 is an enlarged plan view schematically showing a screen of the organic EL display panel 10. In the organic EL display panel 10, an organic EL element 100B that emits blue light, an organic EL element 100G that emits green light, and an organic EL element 100R that emits red light are repeatedly arranged in that order in an X-axis direction of the drawing to form a row. A plurality of the rows are arranged in a Y-axis direction of the drawing. FIG. 1A described above, is a sectional view taken arrows 1A-1A line in the organic EL display panel shown in FIG. 6.

The organic EL element 100B is produced by using an emitting layer 106 composed of a blue light-emitting substance in the organic EL element 100. The organic EL element 100G is produced by using an emitting layer 106 composed of a green light-emitting substance in the organic EL element 100. The organic EL element 100R is produced by using an emitting layer 106 composed of a red light-emitting substance in the organic EL element 100. A set of the organic EL elements 100B, 100G, and 100R constitutes a pixel 200.

### 3. Operation of Organic EL Display Device 1

When an image is displayed on the organic EL display panel 10 in the organic EL display device 1, a predetermined voltage is applied to desired organic EL elements 100 of the organic EL display panel 10 from the drive circuits 21 to 24 through active-matrix. The light emission of the organic EL elements 100B, 100G, and 100R are adjusted by controlling the applied voltage, and each pixel emits light with a predetermined color. Consequently, the organic EL display panel 10 can display a colored image as a whole. The organic EL display panel 10 is not limited to a top emission type or a bottom emission type. A top emission type or a bottom emission type can be selected in accordance with the structure of the organic EL element 100.

### 4. Effects

The organic EL display panel 10 includes the organic EL elements 100 in which the luminescence unevenness and an increase in the driving voltage are suppressed. Therefore, high displaying quality, high reliability, power savings and simplified structure can be achieved. Since an n-type TFT element is used in the organic EL display panel 10, an increase in the luminance variation among pixels is suppressed and the displaying quality can foe further improved, which is advantageous for increasing the size of a screen.

The organic EL display device 1 includes the above-described organic EL display panel 10 and therefore exhibits high performance.

### 5. Modified Examples

In the second embodiment, active-matrix is employed, in the organic EL display panel 10, but passive-matrix may be employed.

In the second embodiment, the organic EL display panel 10 includes a plurality of the organic EL elements 100 arranged in a matrix. However, the arrangement is not limited thereto, and a staggered arrangement or a random arrangement may be employed. The number of the organic EL elements 100 in the organic EL display panel 10 is not particularly limited. For example, only one organic EL element may be formed over the entire screen like an organic EL illumination.

In the second embodiment, the pixel 200 is constituted by the organic EL element 100B that emits blue light, the organic EL element 100G that emits green light, and the organic EL element 100R that emits red light. The type and number of emission colors in the pixel 200 are not limited. For example, only white or four colors of blue, green, red, and yellow may be employed.

In the second embodiment, the organic EL elements 100 have a rectangular shape with, round corners as shown in FIG. 6. However, the shape is not limited thereto, and may be a square shape, a diamond shape, a polygonal shape, a circular shape, an elliptical shape, or the like. In FIG. 6, all the organic EL elements 100 have the same shape, but some or all of the organic EL elements 100 may have different shapes.

In the organic EL display panel 10, each of the organic EL elements 100 does not necessarily include its own functional layers. For example, some or all of the functional layers may be shared by the organic EL elements 100.

In the second embodiment, the organic EL elements 100 are used for the organic EL display device and the organic EL display panel. However, the usage of the organic EL elements 100 is not limited thereto. For example, the organic EL elements 100 may be used for organic EL illumination and the like.

The organic EL element, the method for manufacturing the organic EL element, the organic EL display panel, and the organic EL display device according to the present disclosure can be widely applied to, for example, apparatuses for domestic use, public use, and business use, such as displays, televisions, personal computers, and mobile electronic devices, other various electronic apparatuses having a display function, and illumination apparatuses.

What is claimed is:

1. An organic EL element comprising:
a substrate;
a cathode;
an emitting layer;
a first hole injection layer containing a first organic material whose LUMO level is −4 eV or less;
an anode; and
a second hole injection layer containing a second organic material,
wherein the substrate, the cathode, the emitting layer, the first hole injection layer, the second hole injection layer, and the anode are disposed in that order,
a roughness of a principal surface of the second hole injection layer on the side of the anode is smaller than a roughness of a principal surface of the first hole injection layer on the side of the second hole injection layer, and
L1, L2, and EA satisfy formula (1) below,
−EA−2 eV≦L2≦L1+2 eV (1)
where the first organic material has a LUMO level L1, the second organic material has a LUMO level L2, and the anode has an electron affinity EA.

2. The organic EL element according to claim 1,
wherein the first organic material is the same as the second organic material,
the second hole injection layer further contains a third organic material having a flatness lower than those of the first organic material and the second organic material, and
a volume ratio of the first organic material in the first hole injection layer is higher than a volume ratio of the second organic material in the second hole injection layer.

3. The organic EL element according to claim 2, wherein the third organic material has a hole mobility of 1×10⁻² cm²/Vs or less and an electron mobility of 1×10⁻² cm²/Vs or less when an electric field of 1×10⁴ V/cm or more and 1×10⁶ V/cm or less is applied.

4. The organic EL element according to claim 1, wherein the first organic material is different from the second organic material.

5. The organic EL element according to claim 4, wherein the second organic material has a hole mobility of 1×10⁻² cm²/Vs or less and an electron mobility of 1×10⁻² cm²/Vs or less when an electric field of 1×10⁴ V/cm or more and 1×10⁶ V/cm or less is applied.

6. The organic EL element according to claim 4,
wherein the second hole injection layer further contains a third organic material, and
the third organic material has a hole mobility of 1×10⁻² cm²/Vs or less and an electron mobility of 1×10⁻² cm²/Vs or less when an electric field of 1×10⁴ V/cm or more and 1×10⁶ V/cm or less is applied.

7. The organic EL element according to claim 1, wherein the first organic material is an azatriphenylene derivative represented by chemical formula below, 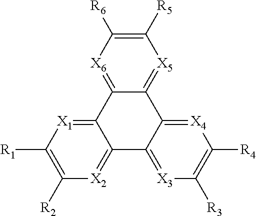
where R₁ to R₆ in the chemical formula each independently represent a substituent selected from hydrogen, a halogen, a hydroxyl group, an amino group, an arylamino group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxyl group having 20 or less carbon atoms, a substituted or unsubstituted aryl group having 30 or less carbon atoms, a substituted or unsubstituted heterocyclic group having 30 or less carbon atoms, a nitrile group, a cyano group, a nitro group, and a silyl group; adjacent Rₘ (m=1 to 6) may be bonded to each other through a ring structure; and X₁ to X₆ in the chemical formula each independently represent a carbon atom or a nitrogen atom.

8. The organic EL element according to claim 1, wherein the first organic material is 1,4,5,8,9,12-hexaazatriphenylene-2,3,6,7,10,11-hexacarbonitrile.

9. The organic EL element according to claim 2, wherein the third organic material is N,N′-diphenyl-N,N′-bis(1-naphthyl)benzidine.

10. The organic EL element according to claim 6, wherein the third organic material is N,N′-diphenyl-N,N′-bis(1-naphthyl)benzidine.

11. The organic EL element according to claim 1, wherein a content of the second organic material in the second hole injection layer is 15 vol % or more.

12. The organic EL element according to claim 1, wherein when the first hole injection layer has a, thickness of T nm, the second hole injection layer has a thickness of 0.06×T² nm or more.

13. The organic EL element according to claim 12, wherein T is 30 or less.

14. The organic EL element according to claim 2, wherein a content of the third organic material in the second hole injection layer is 50 vol % or more.

15. The organic EL element according to claim 6, wherein a content of the third organic material in the second hole injection layer is 50 vol % or more.

16. The organic EL element according to claim 1, further comprising a hole transport layer containing a fourth organic material, the hole transport layer being disposed between the emitting layer and the first hole injection layer,
wherein the fourth organic material has a HOMO level H4, and a difference between L1 and H4 is within 2 eV.

17. The organic EL element according to claim 2, further comprising a hole transport layer containing the third organic material, the hole transport layer being disposed between the emitting layer and the first hole injection layer,
wherein the third organic material has a HOMO level H3, and a difference between L1 and H3 is within 2 eV.

18. The organic EL element according to claim 6, further comprising a hole transport layer containing the third organic material, the hole transport layer being disposed between the emitting layer and the first hole injection layer,
wherein the third organic material has a HOMO level H3, and a difference between L1 and H3 is within 2 eV.

19. The organic EL element according to claim 1, wherein the anode is mainly composed of an alloy of magnesium and silver.

20. An organic EL display panel comprising the organic EL element according to claim 1.

21. An organic EL display device comprising the organic EL display panel according to claim 20.

22. A method for manufacturing an organic EL element, comprising:
forming a substrate, a cathode, an emitting layer, a first hole injection layer containing a first organic material whose LUMO level is −4 eV or less, a second, hole injection layer, and an anode in that order,
wherein
L1, L2, and EA satisfy formula (1) below,
−EA−2 eV≦L2≦L1+2 eV (1)
where the first organic material has a LUMO level L1, the second organic material has a LUMO level L2, and the anode has an electron affinity EA; and a roughness of a principal surface of the second hole injection layer on the side of the anode is smaller than a roughness of a principal surface of the first hole injection layer on the side of the second hole injection layer.
